(19) United States
(12) Patent Application Publication
(10) Pub. No.: US 2019/0124800 A1
(43) Pub. Date: Apr. 25, 2019

(54) Conductive Construction Panel and Method of Use

(71) Applicant: Robert Francis Bodi, Westlake, OH (US)

(72) Inventor: Robert Francis Bodi, Westlake, OH (US)

(21) Appl. No.: 16/165,361

(22) Filed: Oct. 19, 2018

Related U.S. Application Data
(60) Provisional application No. 62/574,413, filed on Oct. 19, 2017.

(51) Int. Cl. H05K 9/00; E04B 1/92; E04F 13/077; E04C 2/292; E04B 2/00; B32B 3/04; B32B 3/06; B32B 15/04

(52) U.S. Cl. CPC H05K 9/0003; H05K 9/0005; E04B 1/92; E04F 13/077; E04C 2/292; E04H 9/04; B32B 3/04; B32B 3/06; B32B 15/04; E04B 2001/925; E04B 2103/06; E04C 2/44

(57) ABSTRACT

An apparatus and method of providing protective panels including a conducting layer and an insulating layer that may be decorative for paneling a wall, ceiling, or floor of a room to protect the room and its contents from damaging electromagnetic fields. Also, the method of using the protective panels to protect vehicles or other devices provided in the room from damage by electromagnetic fields.

### CROSS-REFERENCES TO RELATED APPLICATIONS

This application claims priority from U.S. provisional patent application Ser. No. 62/574,413 filed on Oct. 19, 2017, and incorporated herein by reference.

### BACKGROUND

Various societies around the world have become more and more dependent upon electrical equipment for industry and personal lives. Furthermore, this electrical equipment has become more and more complicated, with more and more devices utilizing sensitive electronics, such as computers for control and operation functions.

This electrical equipment can be overly sensitive to electrical fields, such as may be created by lightning or even solar events such as solar flares or sunspots. Furthermore, modern warfare techniques anticipate the use of Electrical Magnetic Pulse (EMP) weapons that can impact electrical equipment over large geographical areas. The electronics and wiring in electrical equipment can be seriously damaged or even destroyed by exposure to electromagnetic fields of sufficient strength such as may be created by the listed events, among others. Electrical transmission grids themselves are vulnerable to these events, since the long transmission lines and wire coils of transformers act as antenna for such fields, and hence can be adversely impacted by them.

Furthermore, electronic spying techniques have improved over time, and hence any emitted electromagnetic fields may be monitored in an attempt to obtain confidential information.

Desired are devices and methods to avoid such electronic spying and to protect equipment from damage if and when such events electromagnetic occur.

### SUMMARY

Provided are construction materials that permit the building of electronically shielded rooms at relatively low cost and with minimal specialized techniques. Retrofitting existing rooms to become faraday cages is made feasible through the provision of paneling which uses decorative panels having electrically conductive layers that can be electrically interlinked to each other. Provision is made to accommodate the entry of electrical connections, sockets, switches, and lighting to reduce the amount of electromagnetic energy that enters or exits the room (i.e., leakage radiation).

Also provided are additional example embodiments, some, but not all of which, are described hereinbelow in more detail.

### BRIEF DESCRIPTION OF THE DRAWINGS

The features and advantages of the example embodiments described herein will become apparent to those skilled in the art to which this disclosure relates upon reading the following description, with reference to the accompanying drawings, in which:

FIG. 1A is a drawing of a first side of a first example embodiment of a protective panel;

FIG. 1B is a drawing of an example second side that can be used for both the first example embodiment and a second example embodiment of protective panels;

FIG. 1C is a drawing of the first side of the second example embodiment of the example protective panel;

FIG. 2 is a drawing of a wall being paneled using panels of the first example embodiment;

FIGS. 3A, 3B, and 3C are drawings of cross sections of different example embodiments of protective panels showing different layers of design;

FIG. 4 is a drawing of a wall paneled using panels of the second example embodiment;

FIG. 5 is a drawing showing a wall being prepared with conductive strips for paneling using panels of the second example embodiment;

FIGS. 6A and 6B are drawings showing an alternative construction of a protective panel having decorative front portions;

FIG. 7 is a drawing showing a number of the alternative example panels installed on a wall;

FIG. 8 is a schematic drawing of a cross section of an example conductive cover for covering a window in a wall with protective panels;

FIGS. 9A, 9B, and 9C are schematic diagrams of different views of an example socket cover for covering an electrical socket in a wall; and

FIGS. 10A and 10B are schematic diagrams of different views of an example cover for a junction box in a wall.

### DETAILED DESCRIPTION OF THE EXAMPLE EMBODIMENTS

A faraday cage is a device that shields, and hence protects, an interior space from exposure to electrical fields. A faraday cage also prevents electrical fields from exiting the cage, potentially protecting against undesired access to such fields, which could be used to gain information, for example. A faraday cage is basically a chamber that is entirely surrounded by electrically conducting material that prevents the entry (and exit) of electromagnetic fields into (or out of) the chamber interior.

A protective room can be created using the principles of a faraday cage. Note that the enclosure need not necessarily operate as a perfect faraday cage to protect devices put within the enclosure. Merely by attenuating dangerous electromagnetic fields adequately to avoid damage is sufficient. Furthermore, the protective room need not protect against all electromagnetic fields to be effective, since some electromagnetic fields are more likely to occur in dangerous levels, such as the fields created by a natural EMP event (such as may occur by a solar flare, for example), or a man-made EMP event (such as might be created by the detonation of a nuclear device or an EMP generator, for example).

Protective rooms can include garages or sheds to protect vehicles, electronic equipment, generators, and other equipment from damage by dangerous electromagnetic fields, such as provided in an EMP event. Interior rooms of a home or office or other building might also be protected using the disclosed approach to protect communication or other electronic equipment, or to protect the room from surveillance of escaping communication electromagnetic fields by blocking all, or a portion of, such fields. Hence, such a technique might be used to secure rooms from spying activities attempted outside of the room.

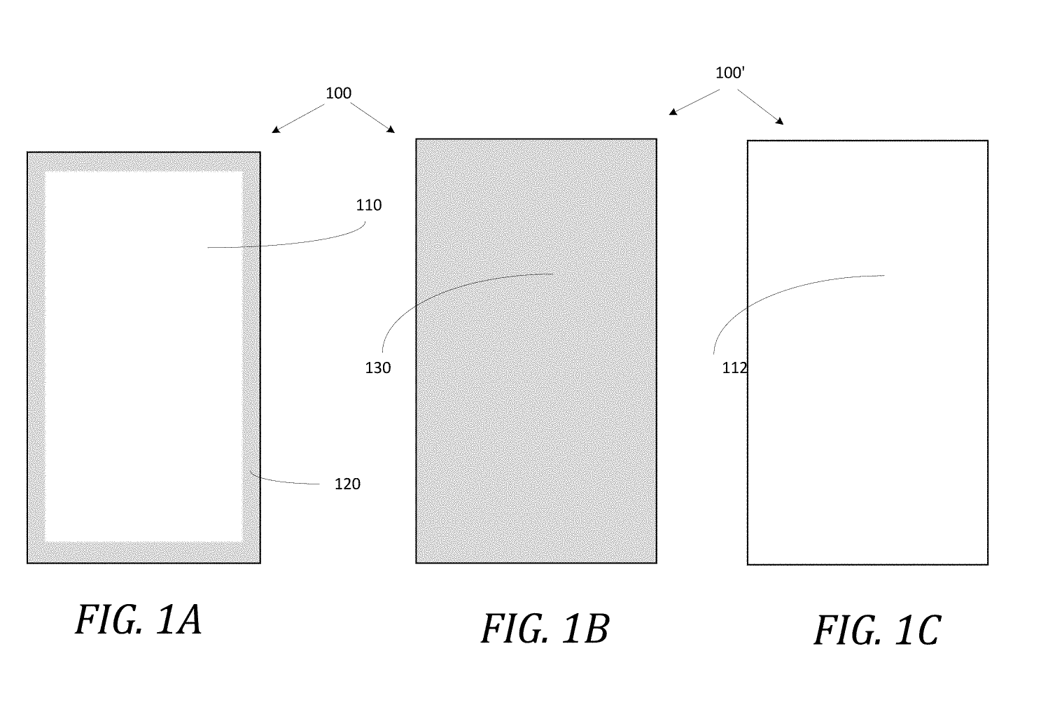

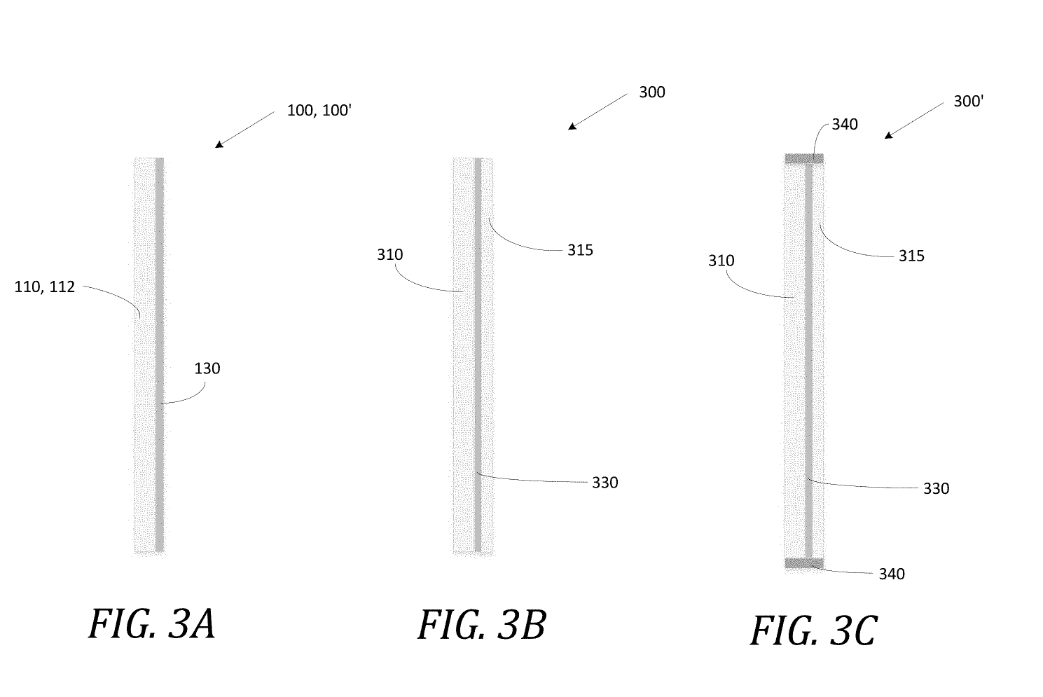

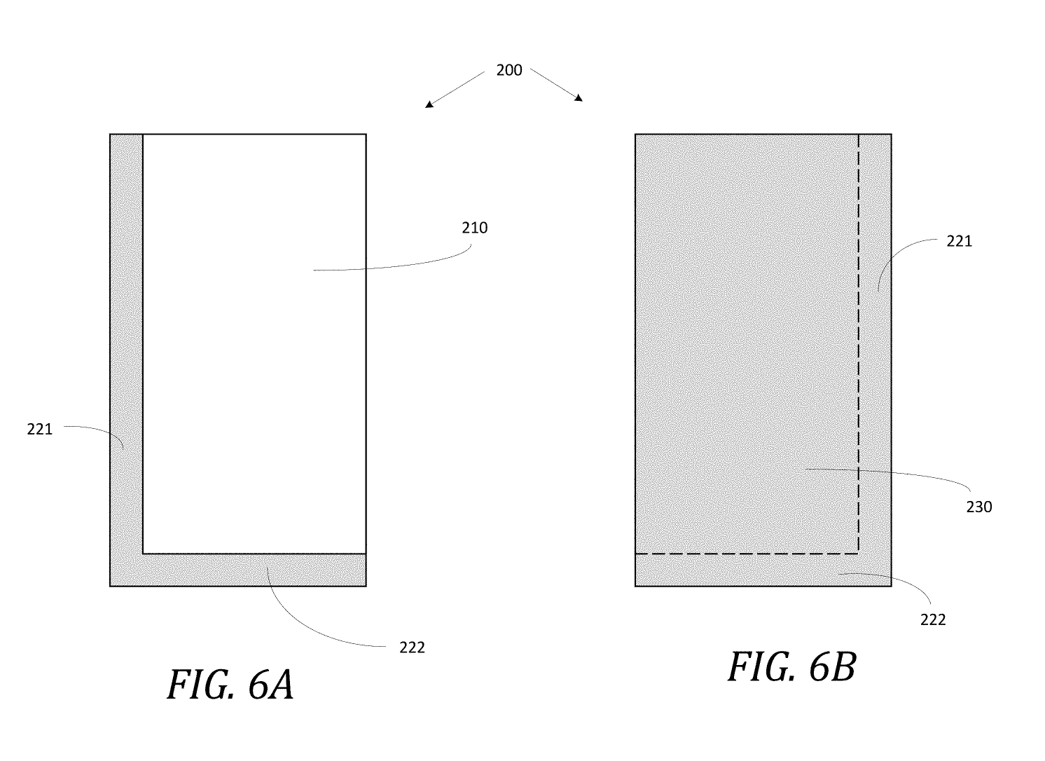

FIGS. 1A and 1B show one example panel that can be utilized for building a protective room that provides some of the benefits of a faraday cage. FIG. 1A shows a front of a panel 100 having an insulating top portion 110 (which may be decorative or paintable) with conducting overlaps 120 around the edges of the panel 100 that might be comprised of a thin conductor material. FIG. 1B shows a back of the panel 100 with a conductive layer. FIG. 3A shows a cross section that an example panel 100 may take, with the insulating layer 110 laminated to a conductive layer 130. The overlaps 130 can be formed by extending the conductive layer 130 beyond the four edges of the layer 110 and folding the extensions over to cover the top of layer 110, thereby forming the conductive overlaps 120. In some cases, the panel 100 might be provided with conductive strips 120 provided on only one or two sides (similar to as shown in FIG. 6A).

The conductive layer 130 may be comprised of a metal foil or thin sheet, or some other alloy, including a conductive metal, such as copper, aluminum, silver, etc. Alternatively, the foil might be of a less conductive metal such as steel, stainless steel, zinc, or nickel, for example. Other alternatives include using a galvanized metal layer or a foil alloy, such as brass or bronze.

As a further alternative, the conductive layer may be comprised of a woven cloth sheet, such as through use of metallic or carbon threads, or a conductive composite or plastic material formed into a sheet or panel that may comprise carbon, metal powders, or other conductive materials could be used. The layer could be a mesh (screen) having gaps sufficiently small to block or sufficiently attenuate the desired frequencies of electromagnetic fields.

Preferable would be using a conductive material to form the conductive layer that is not prone to corrosion, such as stainless steel, low corrosive alloys of aluminum, brass, or carbon composites. Portions of the conductive layer might be treated to minimize corrosion, where the treatment might be easily removed to permit electrical conduction, where desired.

The panels 100 could have the conducting overlaps 120 formed by folding portions of the conducting layer 130 over to the top part of the panel on all four sides. Foil conductive layers can be easily folded to form these overlaps. Alternatively, the conducting overlaps 120 might be formed of an electrical paint or other coating in electrical contact with the conducting layer 130. The conducting layer 130 on the back of the panel, in this approach, might be coated with an anti-corrosion substance or an insulating layer, if desired.

The insulative (optionally decorative) top portion 110 can be formed as a laminated layer, such as shown in the example of FIG. 3A. Such a decorative layer may be a paintable surface, such as plaster drywall panel covered in paper, or it may have a wood composite layer covered with a wall-paper layer, for example. Other alternatives include providing a decorative wooden panel or a simulation thereof, plastic layers, or a layer of any type of material that can be exposed in the room or otherwise painted or papered over, as desired.

The insulative top portion, or another inner layer, could be comprised of a material that has anti-ballistic properties to provide protection against projectiles (e.g., bulletproofing) to a room or container. Acceptable materials may include a high-density polymer (e.g., polyethylene, Tensylon), ceramic, metal (e.g., steel, titanium, and alloys thereof), aramid fiber (e.g., Kevlar), polycarbonate (e.g., Lexan), fiberglass (ArmorCore, see www.armorcore.com), carbon fibers, and other carbon structures, boron treated cloth, etc. and combinations thereof. Ballistic cloths (fabrics), woven fibers, or non-woven fibers, can be used for such panels or as fillers for such panels, such as by laminating such cloths or sheets to the panels, or filling voids in-between panel layers with such materials, with or without other materials such as decorative covers. Such approaches could be used for any of the panel designs described herein, such as by using these materials in the decorative or substrate layers, or as additional layers.

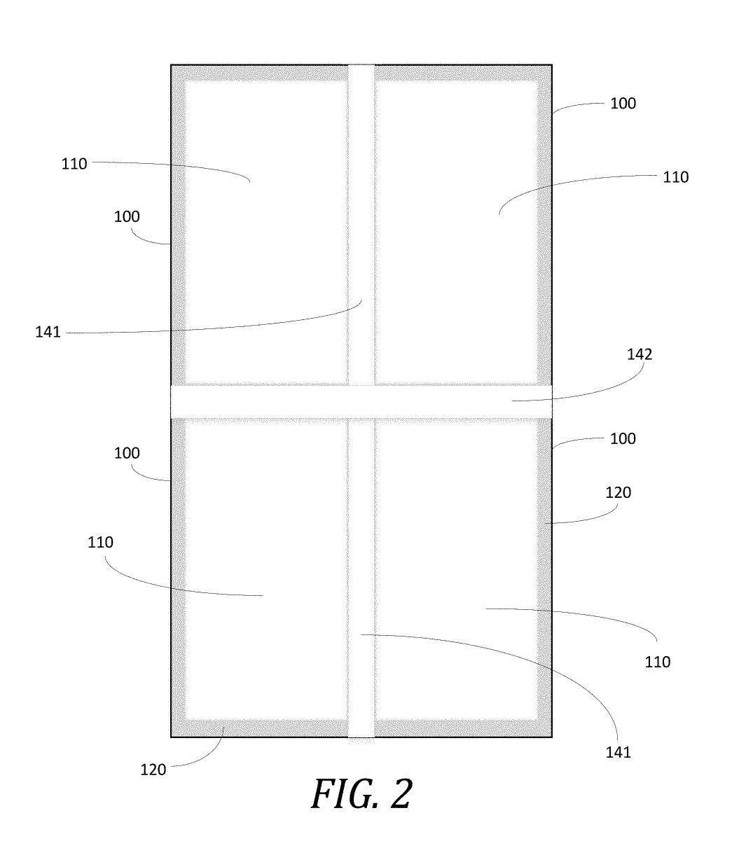

The panels 100 of FIGS. 1A, 1B can be used to panel a wall as shown in FIG. 2. In this example, the panels 100 are mounted adjacent to each other, with the decorative top portion 110 exposed outwardly. The conductive overlaps 120 are covered at adjacent panels by a separate conductive strip 141, 142 that electrically connects the conductive layer of one panel 100 to the adjacent panel(s) 100 by contact with conductive surfaces, so that electrical conductivity is provided over the entire paneled surface. The conductive strips 141, 142 may be a conductive tape that is taped to the wall, for example, or a metal foil that is stapled, nailed, or otherwise attached to the panels. This conductive strip 141 may totally cover the conductive overlap 120, or only cover a portion.

One option is to make the conductive strips 141 an extension of the conducting layer, or otherwise a thin layer of conductor that extends beyond the insulating layer of the panel (see FIG. 6A), rather than as separate strips, such that the wall may be paneled by folding the conductive strip of one panel over onto the top of panel (over the insulating layer), and then placing the panel such that the folded strip is provided in contact with an extended strip of an adjacent panel. In this example, only the back sides of the strips need be conductive. In this way, the strips make electrical contact between adjacent panels. Using such an approach, the strips might be covered with a removable paper or other material on one or both sides to protect the strips from corrosion, with the removable material being removed prior to installation. Furthermore, the conductive layer of the panel might be coated (but not the conductive strips) with a permanent coating to prevent corrosion (e.g., where layer 315 of FIG. 3B is a thin protecting coating used to form the panel)

Note that by paneling all walls, and the floors and ceilings of a room, with the conductive strips 141 of each panel electrically connecting every panel to its adjacent panel(s) (see 141 of FIG. 2), and also using the conductive strips to connect adjacent panels at the corners of the room, the entire room will be surrounded by a conductive layer, and hence act similar to a faraday cage for protecting the interior of the room from electromagnetic fields.

The conductive strips 141 should be comprised of a conductive material that will be placed in contact with the conductive overlaps 120. This strip may include a tape with a conducting adhesive on the contacting surface, or the tape might be comprised of a conductive layer which runs down the center of the tape, with adhesive layers on either side of the conductive layer to hold the tape in place. Alternatively, the conductive strip 141 might be welded to the conductive overlap 120 using heat, such as by spot welding, or the tape might be held in place using staples, nails, screws, glue, or some other type of fasteners.

It is noted that it may be preferable to attach the panels to the underlying walls using a conductive fastener, such as metal nails, screws, or staples, so that any holes created in the panel are filled with a conductor. Alternatively, the panels could be glued to the walls.

Note that later in this disclosure means of allowing electrical wiring to accommodate lights, electrical sockets, and switches, and other electrical equipment, will be discussed.

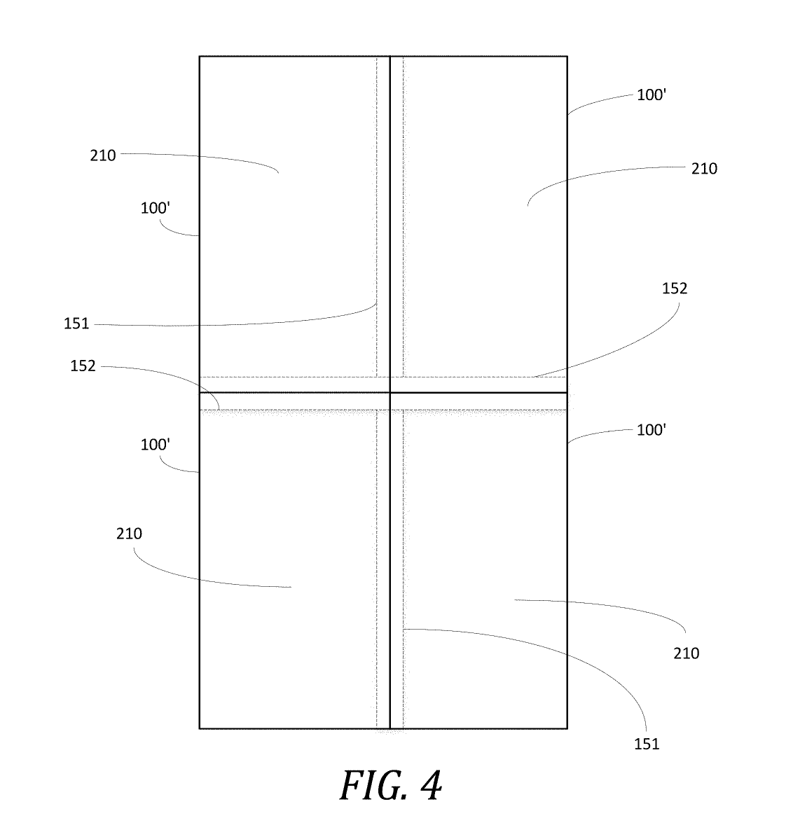

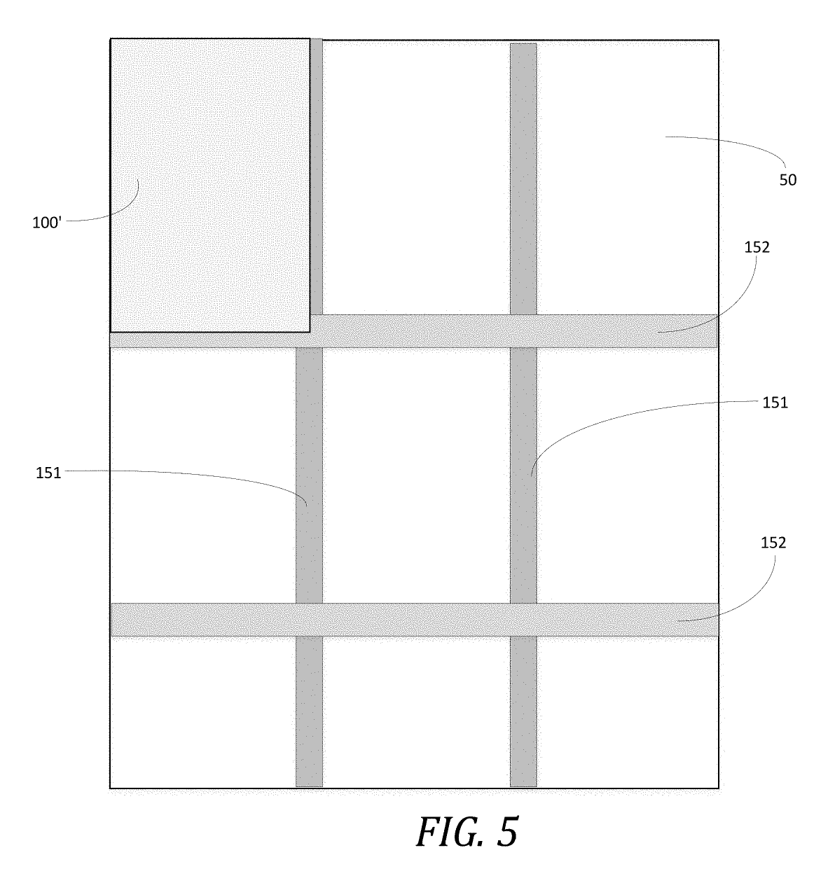

FIG. 4 shows an alternative embodiment that does not require the use of the electrical overlaps 120. For this case, alternative panels 100′ would be used that merely utilize a decorative top portion 112 and conductive layer 130, with no overlap portions needed, as shown in FIGS. 1B, 1C. The back conductive layer 130 can remain as shown in FIG. 1B. For this embodiment, the panels 100′ are electrically connected using a conductive strip 151, 152, such as a conductive tape with an outer (front) conducting surface and not necessarily using a conducting glue on the back side, that is provided under the panels (as shown by the broken lines), which can be applied directly to the wall 50, as shown in FIG. 5. The decorative top portion 112 can be provided as described for decorative top portion 110. Alternatively, strips of foil or thin metal can be attached to the wall using fasteners (e.g., nails, screws, staples, etc.), glue, or other methods of fastening.

FIG. 5 shows a wall with conductive strips 151, 152 applied to the wall with one panel 100′ installed on the wall. Note that the strips 151, 152 are only partially covered by the one panel 100′ so that adjacent panels, when installed, will contact the uncovered portions of the strips to provide electrical conductivity between adjacent panels. Additional panels can then be installed, resulting in all of the panels on the wall being in electrical contact with each other by connecting their conducting layers together using the conductive strips, providing a uniform conductive layer that avoids gaps for any electric filed leakage.

In this case, conductive tape 152 is applied to the walls horizontally, and conductive tape 151 is applied to the walls vertically, in a position that overlaps adjacent ends of panels to be installed on the wall. The tape 151, 152 may be of the same type. The outer (top) portion of the conductive tape 151, 152 will be conductive and hence will contact the conductive layer 130 of the panel 100′ when the panel is installed, and since the conductive tape is installed to overlap adjacent panels, this will then electrically connect all adjacent panels to each other. Note that the materials used for the conductive strips and the conductive layers of the panels should be compatible chemically so that they do not cause corrosion after installation.

Note that conductive tape can be put in or around corners, or special corner strips can be provided, to allow panels on adjacent walls, or walls next to ceilings and/or floors, to be electrically connected to each other. Alternatively, thin metallic corner brackets could be put in or on the corners to achieve the same purpose.

One advantage of this approach is that any adhesive portion of the conductive strips 151, 152 that might be used to hold the strip onto a wall (e.g., a conductive tape) need not be conductive, and only the outer layer of the tape need be conductive to electrically connect adjacent panels to each other. Alternatively, the tape may be mounted on the wall using fasteners, such as staples, nails, screws, etc. Or adhesive or fasteners may be applied separately to the conductive strips during installation, rather than having an adhesive layer already provided on the strips.

In any case, it is desirable that any conductive strips to be used for direct wall application have some substantial thickness to ensure that the tape fully contacts the conductive layer 130 over its length, to avoid gaps that could allow the entry or escape of electromagnetic fields. Alternatively, the tape may have an uneven surface layer, such as using ribbed, bubbled, tabs, or other types of raised portions to ensure connectivity. Alternatively, a conductive foam layer or a conductive adhesive layer might be utilized to ensure continuous electrical contact, or a conductive glue or other coating might be used to bind the conductive strips to the conductive layer of the panels.

To avoid corrosion effects, it is desirable for any of the embodiments that the conductive layer of the conductive tape that is in contact with the conductive layer 130 not chemically interact with the conductive layer 130 of the panels 100′ in a way to induce corrosion or electrical currents, and hence similar or compatible conductive layers should be used.

FIG. 3B shows an alternative laminate construction of a conductive panel 300. In this example, the conductive layer 330 is sandwiched between a decorative top portion 310 and a substrate layer 315. This approach may be desirable to protect the conductive layer from harm during transport, handling, and/or installation. The substrate layer 315 may provide added strength to the panel as well, or it could provide an adhesive layer to aid in installation. The decorative top portion 310 may be provided as described for decorative top portion 110 or 112, hereinabove.

Note that a final construction of a conductive panel could utilize a single conductive layer that is painted or papered on one surface to provide a decorative effect, which could be used similar to the panel 100′ in application.

Alternatively, the layer 325 might provide an additional decorative surface so that each panel has two different decorative options. For example, the layer 310 may provide a textured surface, such as a simulated wood, whereas the layer 315 could be layer that can be painted or papered over.

The panel 300 could be designed to use conducting overlaps as used in the example of FIG. 1A, such that the conductive layer 320 extends beyond the edges of the panel 300 and are folded over the decorative top layer 310, in which case the installation process would proceed similar to that for the panels 100, using a conductive strip (e.g., tape) over the top edges of adjacent panels.

Alternatively, the conductive overlaps could be folded over the substrate layer 315, in which case the installation process would proceed similar to that for the panels 100′ in that the conductive tape would be placed on the walls to contact the underlying overlaps.

As a further alternative, either type of laminate 100 (100′) or 300 could be provided with conductive edges, such that a conductor edge 340 is provided around all four the outer facing edges of a panel 300′, as shown in FIG. 3C for a three-layer laminated panel of FIG. 3B. Similarly, such a conductor edge could be used for the two-layer panel of FIG. 3A in a like fashion.

These conductive edges 340 would be on all four edges of the panel, and would be in electrical contact with the respective conductive layers 130 or 330, as the case may be. During installation, rather than using conductive strips (or in addition to using the conductive strips), the conductive edges 340 of respective panels can be put into electrical contact with each other to better enable continuity of electrical conductivity across the installed surface.

To better ensure that electrical conductivity is maintained, the conductive edges 340 may be comprised of a conductive foam, or else have a foil surface with a conductive foam substrate, so that adjacent panels can be put into minor compressive force with each other to better ensure electrical contact between the conductive edges 340 of adjacent panels.

Note that in panels that utilize conductive overlaps formed by folding the conductive layer 130, 330 over the panel onto the top surface forming the strips 120 of FIG. 1A is an approach that effectively provides a conductive edge 340 to the panels that can be utilized as-is to enhance the electrical conductivity of adjacent panels (as described above), or which can be further enhanced by adding a further conductive edge on top of the folded-over edge of the conductive foldover.

FIGS. 6A and 6B show a further alternative construction of a conductive panel 200. In this embodiment, FIG. 6A shows a front of the panel 200 which has a decorative top portion 210 and conductive flaps 221, 222 that extend beyond the decorative top portion 210. FIG. 6B shows the back of the panel 200, with a conductive layer 230 that forms the conductive flaps 221, 222 by extension. Hence, the conductive layer 230 can be extended beyond the layer forming the decorative top portion 210 to form the flaps 221, 222. Alternatively, the flaps 221, 222 might be comprised of strips separate from the conductive layer 230, but electrically connected thereto. Here, the conductive layer 230 may be a foil, mesh, cloth, or some other conductive material as described above for providing conductive layers of the other embodiments.

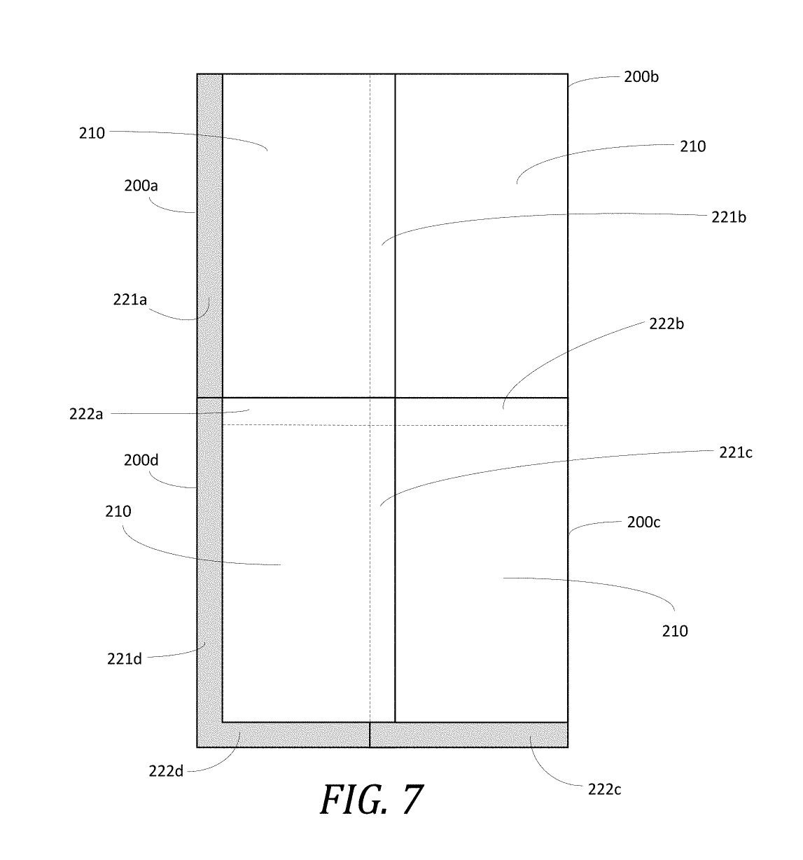

FIG. 7 shows four installed panels 200a, 200b, 200c, and 200d all using the panel 200. The conductive flap 221b of panel 200b is placed under panel 200a in contact with the back conductive layer of panel 200a, as indicated by broken lines, whereas the conductive flap 222b of panel 100b is placed under panel 200c, as also indicated by broken lines. The conductive flap 222a of panel 200a is placed under panel 200d in contact with the back conductive layer of panel 200d, as indicated by broken lines, whereas the conductive flap 221a of panel 200a remains exposed since no panel has yet been installed over it.

Similarly, conductive flap 221c of panel 200c is installed under panel 200d in contact with the conductive layer under panel 200d. Conductive flaps 221d and 222d of panel 200d, and conductive flap 222c of panel 200c, all remain exposed since no panels have yet been installed over them.

In this manner, the conductive flap of one panel is used to make electrical contact with the conductive layer of its adjacent panel. The conductive flaps can be folded into or over corners to allow conductivity to pass to adjacent walls, ceilings, or floors. Once all panels are installed, any exposed conductive flaps might be cut off, as desired. The conductive flaps might be provided having one or both sides covered with a removable layer of paper or other material to protect the surfaces from corrosion. Note that the conductive layer on the back of the panels may also have a removable strip of material on the sides opposite to the strips to protect those portions of the conducing layer from corrosion and damage (or the entire back portion might be covered with a removable layer), whereas the remainder of the conducting layer on the back not to contact the conducting falp of an adjacent panel might be permanently coated with an anti-corrosive layer or coating to protect it from corrosion or damage.

Note that the panels 200 could also utilize the conductive edges described above to provide further electrical contact between adjacent panels, if desired.

In some cases, a tape and/or plaster may be applied over the seams between top portion of installed panels to cover those seams in a manner similar to the way drywall is installed. In other cases, the conductive edges 340 may be provided with a decorative exposed surface on their edge(s) to enhance the decorative effect of the installed panels.

Specialized panels may be constructed for use on floors or ceilings. In particular, floor panels may need to be stronger and more durable in order to support the weight and traction of people and/or vehicles, and hence, the use of multiple layered panels, such as shown in FIG. 3C, may be particularly desirable. Alternatively, panels comprised primarily of a conductive layer may be utilized. Floor panels may use top layers that are strong and durable, such as concrete, cement, stone, etc. or may be adaptable to being covered with such materials. In some cases, a coated metal sheet may be used for floor panels.

For example, metal sheets or conductive cloth or mesh (screens) materials may be embedded in a concrete or asphalt floor to protect the room from electromagnetic penetration via the floor, with these conducting materials being put in electrical contact with the conducting layers of wall panels. Alternatively, a conductive cloth or mesh might be glued or otherwise attached to the floor and put in electrical contact with the conductive layers of adjacent wall panels using conductive strips or conductors, or the cloth or mesh may be placed to overlap a portion of the wall prior to installation of the wall panels to provide such electrical connections using techniques disclosed herein. Even unattached cloth conductors could be used to cover such floors, which may be then covered using more durable panels or other materials for decorative or protective purposes.

In any case, it is noted that in order to form an effective means of suppressing electromagnetic fields, the floor panels should electrically contact at least portions of any conductive wall panels, which should also electrically contact conductive ceiling panels, so that the entire room in encapsulated within continuous, or nearly continuous, conductive layers in all surfaces. Note that small gaps that are smaller than the wavelength of electromagnetic frequencies desired to be blocked may be acceptable, but generally large portions of the walls, ceilings, and floors must have contiguous electrical layers to effectively block or attenuate electromagnetic fields.

Although the conductive panels described hereinabove can be used to adequately address the majority of the exposed surfaces in a room, most rooms have access points for ingress and egress of people, vehicles, and sources of energy, such as doors, windows, and gas and power entries. Devices that can aid in supporting such features are described in the following sections.

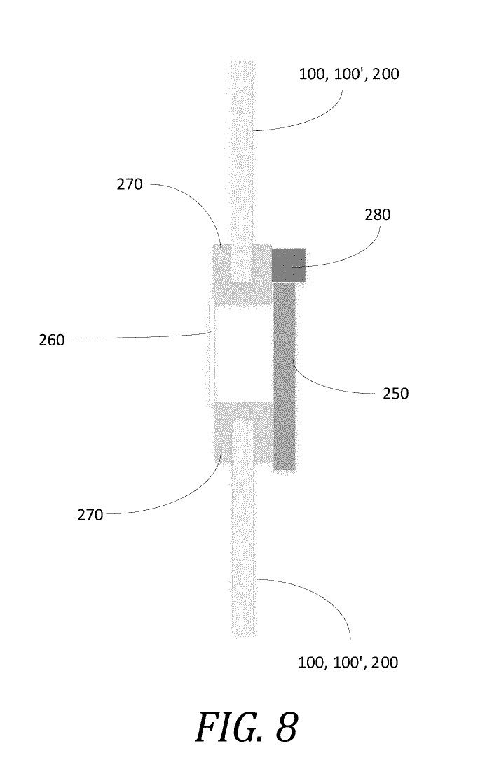

FIG. 8 shows a cross section of an example embodiment of a conductive cover 250 for use with a window 260. The cover has a hinge 280 for opening and closing the cover to control the flow of light and/or air. The conductive panels 100, 100′, 200, or other embodiments can be provided with conductive end caps 270 that contact the back conductive layer of the conductive panels and provide a conductive path to the conductive cover 250, which is put in electrical contact with the conductive end caps 270.

The conductive end caps 270 will be provided on all four sides of the window 260 in contact with panels that surround the window frame. When closed, the conductive cover 250 will be in electrical contact with all of the conductive end caps so that a continuous electrical connection is made to all of the panels surrounding the window frame, with few or no gaps to ensure that the window is sealed from electromagnetic radiation.

The conductive end caps 270 can simply be comprised of a thin metal strip formed into a U shape that snaps or otherwise connects to ends of the panels, having an inner gap that matches the thickness of the panes, with conductive surfaces that are configured to contact the conductive layer of the panels and a conductive portion of the conductive cover. The gap in the end caps can be made tight so that the caps stay in place on the panels. Note that the conductive end caps might replace decorative molding and/or window sills that are typically used around windows, and hence may be fashioned in a decorative manner to improve the aesthetics of the room. The original window sill might be replaced with a conductive window sill provided under the cover 250 but that provides an electrical connection to the cover using a conductive tab or bar, for example, with the window sill contacting the conductive layer of any panel provided under the window sill.

Alternatively, a flexible conducting strip or conducting tape as described elsewhere in this document might be used for the end caps. Or a fastener having a conducive portion put under the panel (such as a washer) might alternatively connect the conductive cover 250 to the conductive layer of one or more adjacent panels.

The conductive cover 250 may be comprised of a conductive panel, such as described above, or another type of conductive panel or board or sheet, or might be a metal cover or door. The conductive cover should have a conductive layer that mostly or completely covers the window opening with exposed electrical surfaces to contact the conductive end caps 270. For example, a conductive panel constructed as the panel 100′ in FIGS. 1B, 1C sized for the window could be used, such that the conductive layer 130 is provided in the inner portion of the cover 250 to contact the conductive end caps. The other conductive panels could be similarly utilized with appropriate modifications to ensure electrical conductivity across the window frame. As discussed above, conductive foams or ribbing or other features can be utilized to improve the electrical connection, and a conducting fastener(s) can be used to further improve electrical conduction.

A latch or lock could be provided to hold the cover 250 closed, as desired, which may be made electrically conductive to improve conduction. To ensure electrical conductivity, the conductive end caps might be provided with a foam or other resilient layer to allow for compressive forces to ensure conductivity is maintained. Even a conductive foam could be used as described above.

A conductive door cover could be similarly provided in a door frame, absent the window, to cover the entire door frame and put it in contact with conductive panels around the door and on the floor. As an alternative, a metal door might be used that is configured to contact the conductive panels surrounding the door frame, such as by using a device similar to the conductive end caps 270, or by using a conductive weather stripping, or some other means of ensuring continuous electrical conductivity with minimal or no gaps when the door is closed. Alternatively, a shade or curtain or other conducting cover might be used to cover the door (either permanently or in a removable manner, such as by a mechanical shade device) to provide the desired features.

A protective larger door, such as a garage door, can be provided with door panels that are electrically conductive and connected to each other using conductive molding or strips or other features as discussed herein. Alternatively, a conductive cover for the door, such as a metallic corrugated screen, shutter, or other covering can be added to provide the desired protection from electromagnetic fields.

In order to accommodate entry of electrical wires to power equipment in the room, specialized conductive socket covers and/or junction boxes can be provided.

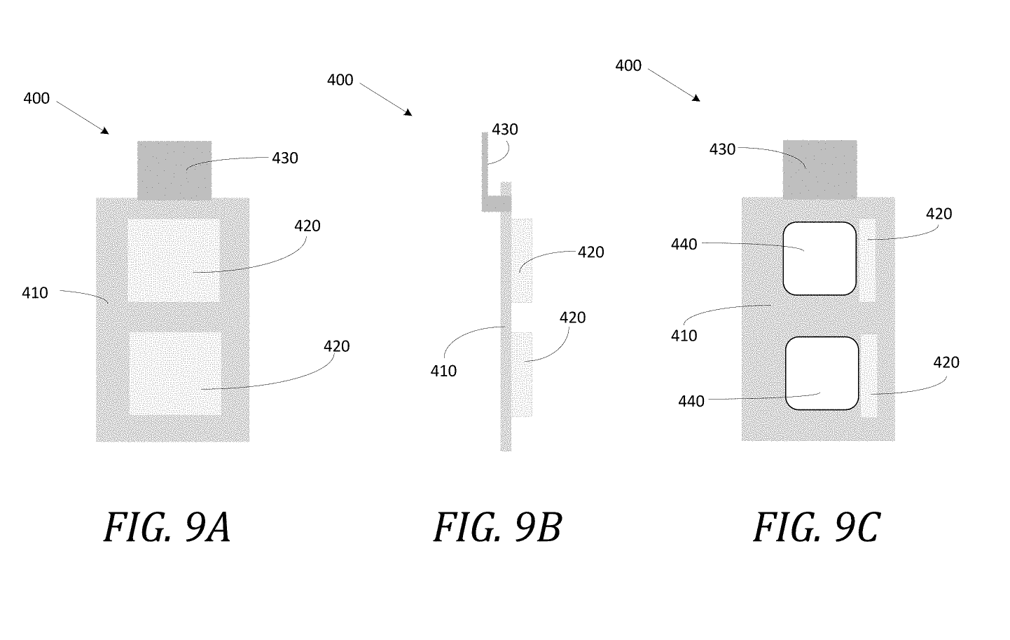

FIGS. 9A, 9B, 9C show different views of a socket cover 400 that could be utilized. The socket cover has a conductive main body 410 that may have a decorative exposed surface. The socket cover has hinged conductive socket caps 420 in electrical contact with the conductive main body 410, and that can be opened to expose an opening 440 to allow access to electrical sockets, as shown in FIG. 9C (front view) and closed to cover the opening 440 as in FIGS. 9A (front view) and 9B (side view).

A conductive bracket 430 is provided in electrical contact with the conductive main body 410 around a periphery of the socket cover 400. The conductive bracket has an exposed electrical contact surface that points outward and that is put under a conductive panel at a cutout to expose the sockets. The exposed electrical contact surface is put into contact with the conducting layer of the conductive panel either by directly contacting the panel on the back of the panel, or by some other means, such as by using edge conductors on the panel cutouts, for example.

Note that in order to aid in installation, the conductive bracket may be made removable from the socket cover main body 410, and held in place by one or more screws, so that the conductive bracket can be put in place under the panel prior to installing the socket cover 400. Furthermore, the bracket may be made in two or more pieces, so that the cover can be more easily inserted under the panel, with the pieces being made to be in electrical contact with each other once fully installed. Another alternative is to use a conducting foam as the conductive bracket, so that it can be inserted under the panel by flexing the bracket to allow proper placement.

Another alternative is to replace the conductive bracket with a flexible metal foil or sheet that is folded around the cutout to be put into contact with the conductive layer of the panel, and then to provide an exposed electrical contact at the cutout region on top of the panel. Then, exposed electrical contact portions can be provided on the socket cover 400 to contact the exposed electrical contact portion of the foil or sheet.

Note that when in an open position to expose the electrical sockets, the opening provides some non-conductive portions that may allow some leakage of electromagnetic radiation into or out of the room. This can be minimized through use of specialized electrical sockets that have electrical conductive portions that further reduce the size of any unprotected gaps. For example, the plastic portions of a socket near the socket holes might be filled with a conductive material. Also, it would be possible to provide specialized sockets and plugs that are smaller in size and still further reduce any plugs or gaps.

Note that because electromagnetic radiation can also enter and exit a room through electrical wiring, filters, surge protectors, ferrite rings or loops, and other devices could be used to reduce such leakage.

Note that a light switch cover could be provided in a similar manner as the socket cover 400 by having a cover 420 and opening 440 configured to accept a switch.

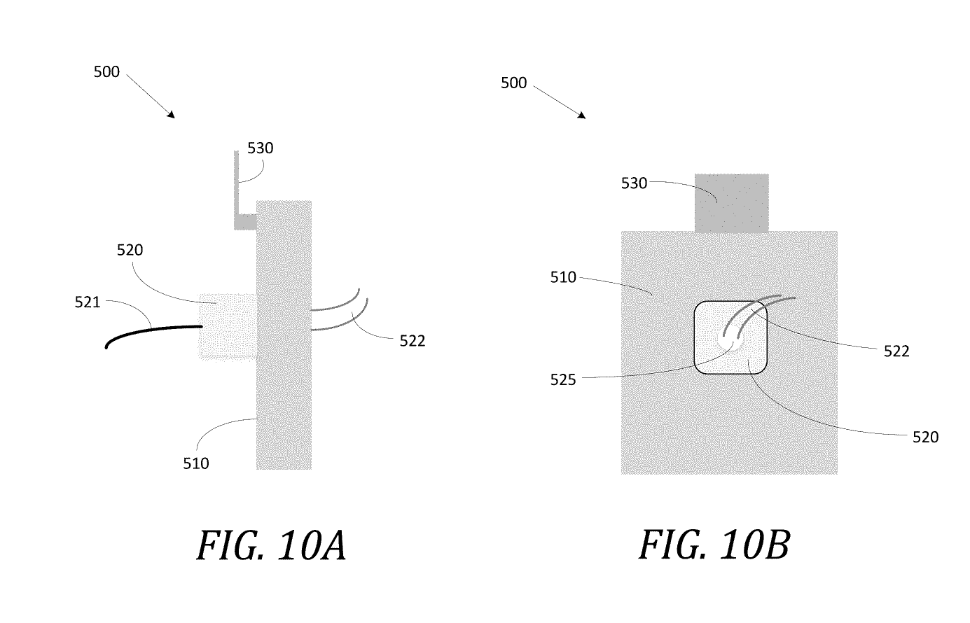

FIGS. 10A, 10B show side and front views, respectively, of a junction box 500 that can be used to reduce electromagnetic radiation leaks into and out of a room. The box has a main hollow body 510 that provides a passage for electrical wires into a room. A conductive bracket 530 can be provided in a manner similar to the bracket 430 described above, and the other means of providing electrical contact discussed for the socket cover 400, above, could also be used to provide electrical contact between the junction box 500 and the conductive panel in which it is installed via a cutout.

A surge protector/filter device 520 can be provided between the building electrical wiring 521 and the room wiring 522 to further stop any leakage radiation. Entry hole 525 can be minimized in size, or even filled with a conductive material to further reduce leakage radiation.

These various components can then be used to build or retrofit a room to provide electromagnetic field attenuation or blocking. The walls, ceilings, and floors are covered in protective panels such as described herein, and doors, windows, and electrical penetrations can be similarly treated as discussed herein to form a protective room, such as a garage, shed, or other room that can protect contents from electromagnetic damage or exposure.

Many other example embodiments can be provided through various combinations of the above described features. Although the embodiments described hereinabove use specific examples and alternatives, it will be understood by those skilled in the art that various additional alternatives may be used and equivalents may be substituted for elements and/or steps described herein, without necessarily deviating from the intended scope of the application. Modifications may be necessary to adapt the embodiments to a particular situation or to particular needs without departing from the intended scope of the application. It is intended that the application not be limited to the particular example implementations and example embodiments described herein, but that the claims be given their broadest reasonable interpretation to cover all novel and non-obvious embodiments, literal or equivalent, disclosed or not, covered thereby.

What is claimed is:

1. A protective paneling system comprising:
a protective wall or ceiling panel including:
an insulating layer comprising an insulator, and
a conducting layer comprising a conductor configured to dissipate an electric field; and
a conductive strip configured to electrically connect the conducting layer of one panel to the conducting layer of an adjacent panel.

2. The paneling system of claim 1, wherein said conductive strip is part of the protective wall or ceiling panel comprised of a portion of the conducting layer extending beyond the insulating layer configured for contacting the conducting layer of an adjacent panel when installed in a wall or ceiling.

3. The paneling system of claim 1, wherein said conductive strip is comprised of a conductive strip configured to attach to a wall or ceiling, respectively, and configured to electrically connect the conducing layer of one panel to the conducting layer of an adjacent panel both installed on a wall or ceiling.

4. The paneling system of claim 1, wherein a plurality of said protective panels configured with respective panel overlaps forms a mostly continuous conductive surface configured to protect a wall or ceiling from penetration by at least a portion of an electromagnetic field.

5. A method of protecting an interior of a room from an electromagnetic field by paneling the room with a plurality of the panels of claim 1 all electrically connected together to form a mostly continuous conductive surface.

6. The paneling system of claim 1, further comprising a second insulating layer such that the conductive layer is provided between the two insulating layers.

7. The paneling system of claim 1, wherein the insulating layer is provided with a decorative or painted outer surface.

8. The paneling system of claim 1, further comprising a protective cover to protect a window or other opening of a wall from undesired penetration by the electromagnetic field through the window or other opening.

9. The paneling system of claim 1, wherein said conductive strip is provided along an edge of the panel provided in electrical contact with the conductive layer.

10. A protective paneling system comprising:
a protective panel including:
an insulating layer comprising an insulator, and
a conducting layer comprising a conductor configured to dissipate an electric field;
a conductive strip configured to electrically connect the conducting layer of one panel to the conducting layer of an adjacent panel; and
a protective cover to protect a window or other opening of a wall from undesired penetration by the electromagnetic field through the window or other opening, wherein
a plurality of said protective panels are configured with respective conductive strips and at least one protective cover to form a mostly continuous conductive surface configured to protect a wall or ceiling from penetration by at least a portion of an electromagnetic field.

11. The paneling system of claim 10, wherein said conductive strip is part of the protective wall or ceiling panel comprised of a portion of the conducting layer extending beyond the insulating layer configured for contacting the conducting layer of an adjacent panel when installed in a wall or ceiling.

12. The paneling system of claim 10, wherein said conductive strip is comprised of a conductive strip configured to attach to a wall or ceiling, respectively, and configured to electrically connect the conducing layer of one panel to the conducting layer of an adjacent panel both installed on a wall or ceiling.

13. A method of protecting an interior of a room from an electromagnetic field by paneling the room with a plurality of the panels and at least one protective cover of claim 10 all electrically connected together to form a mostly continuous conductive surface.

14. The paneling system of claim 10, further comprising a second insulating layer such that the conductive layer is provided between the two insulating layers.

15. The paneling system of claim 10, wherein the insulating layer is provided with a decorative or painted outer surface.

16. The paneling system of claim 10, wherein said conductive strip is comprised of a conductive strip provided along an edge of the panel provided in electrical contact with the conductive layer.

17. A method of protecting contents of a room from damage by electromagnetic radiation, comprising the steps of:
providing a protective wall or ceiling panel including: an insulating layer comprising an insulator, and a conducting layer comprising a conductor configured to dissipate an electric field;
paneling the walls and ceilings of the room with a plurality of said panels, wherein the conducting layer of each of said panels is electrically connected to the conducting layer of adjacent panels;
preparing a floor of the room with a conductive material that is electrically connected to wall panels adjacent to the floor; and
covering penetrations of the wall, if any, with respective protective covers.

18. The paneling system of claim 17, wherein each of said panels is electrically connected to the conducting layer of adjacent panels using a conductive strip that is provided as part of the protective wall or ceiling panel comprised of a portion of the conducting layer extending beyond the insulating layer configured for contacting the conducting layer of an adjacent panel when installed in a wall or ceiling.

19. The paneling system of claim 17, wherein each of said panels is electrically connected to the conducting layer of adjacent panels using a conductive strip configured to attach to a wall or ceiling, respectively, prior to the installation of the respective panels and configured to electrically connect the conducing layer of one panel to the conducting layer of an adjacent panel.

20. The paneling system of claim 17, wherein each of said panels is electrically connected to the conducting layer of adjacent panels using a conductive strip provided along an edge of each of the panels provided in electrical contact with the conductive layer of the respective panel.

21. The paneling system of claim 17, wherein the insulating layers of the panels are provided with a decorative or painted outer surface.
